(19) United States
(12) Patent Application Publication
(10) Pub. No.: US 2006/0134317 A1
(43) Pub. Date: Jun. 22, 2006

(54) Method for making multifunctional organic thin films

(76) Inventors: Yang Yang, Los Angeles, CA (US); Yan Shao, Los Angeles, CA (US)

Correspondence Address: VENABLE LLP, P.O. BOX 34385, WASHINGTON, DC, 20045-9998, US

(21) Appl. No.: 10/542,791

(22) PCT Filed: Jan. 29, 2004
(86) PCT No.: PCT/US04/02710

§ 371 Date: Jul. 20, 2005

Related U.S. Application Data
(60) Provisional application No. 60/444,788, filed on Feb. 3, 2003.

(51) Int. Cl. B05D 5/12; B05D 5/06

(52) U.S. Cl. 427/78; 427/66

(57) ABSTRACT

A method for use in making electronic and photonic devices wherein said devices include at least one multifunctional organic layer. The method involves first providing a substrate having a surface onto which a multifunctional organic layer is to be deposited. A single evaporation source is provided that includes a mixture of at least two organic compounds. The organic compounds can be matrix materials, and dopants if desired, that are used in making electronic and photonic devices. The single evaporation source is heated for a sufficient time and at a sufficient temperature to provide deposition of the organic compounds onto the surface of the substrate to form the multifunctional organic layer.

### BACKGROUND OF THE INVENTION

1. Field of the Invention

The present invention relates generally to methods for fabricating the organic thin films that are used in a variety of electronic and photonic devices. More particularly, the present invention involves methods for thermally depositing the organic thin films.

2. Description of Related Art

The publications and other reference materials referred to herein to describe the background of the invention and to provide additional detail regarding its practice are hereby incorporated by reference. For convenience, the reference materials are numerically referenced and grouped in the appended bibliography.

Organic thin films have been extensively utilized in various electronic and photonic devices. Examples include Organic Light Emitting Diodes (OLEDs), Organic Thin Film Transistors (OTFTs), Organic Solar Cells (OSCs), Organic Bistable Devices (OBDs), and Organic Diodes (ODs). In order to achieve the desired performance of the device, the device structures are usually complicated and include multiple layers with different functionalities. For example, efficient organic LEDs are usually composed of four to six layers of organic materials wherein each layer has a different function. The fabrication of the various layers is usually a non-trivial matter and is most often time consuming. Accordingly, the present fabrication procedures are not ideal for mass production where high throughputs are required.

To make the situation more complicated, sometimes each individual layer is also quite complicated to construct. Very small amounts of functional dopants (often approximately 1% or less) are often introduced to achieve desired function. For example, dye dopants are used for efficient energy transfer and light-emitting purpose. The control of the small amount of dopants is usually done by the control of evaporation rate which tends to be time consuming and difficult to achieve. For organic layers which are composed of multiple organic compounds, the compounds are divided into two categories: 1) the host matrix material and 2) the dopant material. This is according to the amount of the organic compounds used. Usually, the dopants are a very small amount, in the range of a few percent. The host (or matrix) material usually has the desired film forming property and some physical property, such as light emitting or carrier transporting properties. For dopants, they usually have the desired functional property to compensate or to enhance that of the host material.

A basic OLED is shown at 10 in FIG. 1. The OLED includes a metal layer 12, an electron injection layer 14, an active layer 16, a hole injection layer 18 and a layer 20 of indium tin oxide (ITO). OLEDs of the type shown in FIG. 1 may be made according to a variety of thin film fabrication procedures. For example, a green OLED with Alq₃ as the host material can be fabricated in three ways. First, the traditional method involves adding green dye dopant into Alq₃ directly, as shown in FIG. 2(a). In this case the Alq₃ is matrix material used as the electron transport layer and the green dye is the dopant to harvest the emission. In this device structure, a hole transport layer is needed to facilitate the hole transport into the device. The hole transport layer (HTL) and the electron transport layer (ETL) form a heterojunction for charge accumulation and confinement, where the electrons and holes meet and recombined. [1,2]. A second method involves adding a small amount of green dye dopant into a uniformly mixed layer of ETL and HTL as shown in FIG. 2(c). A third process is the co-evaporation process that is used to form structures as shown in FIG. 2(b). Structures as shown in FIG. 2(b) are referred to as “gradient junction” structures because the junction does not have distinguished ETL and HTL layers. Rather, a gradient mixture of ETL and HTL at the interface is formed by the co-evaporation process. [3,4] The concentration of the ETL and HTL is adjusted gradually in an opposite way. The HTL decrease slowly, from 100% down to 0%. In the meantime, the ETL increases from 0% to 100%. These positive and negative gradients of ETL and HTL layers overlap approximately 100 Å of thickness within an OLED. (FIG. 1b) The small amount of dopant is added to the mixed layer through the co-evaporation process. From the above description, one can realize that organic thin films are presently being prepared via complicated processes that require very fine control of the host and dopant materials.

The most common technology for preparing organic films with dopants is the co-evaporation process. The concentration of each compound is controlled by the evaporation rates of different compounds respectively. Since the amount of dopant is very small, it is indeed difficult to prepare the organic thin films with precise amount of dopants. This process becomes further complicated if more than one matrix or dopant is involved. There is therefore a present need to provide a new method that simplifies the process of preparing multifunctional organic thin films and enables high throughput and high-quality OLEDs manufacture, as well as other organic electronic devices.

### SUMMARY OF THE INVENTION

The present invention provides new methods for preparing multifunctional films using a single source evaporation method. Unlike multiple source evaporation methods, this method does not require the precise control of multiple evaporation boats, and it is ideal for simple and high-speed evaporation and device fabrication.

The methods of the present invention are intended for use in making electronic and photonic devices wherein the devices include at least one multifunctional organic layer. The method involves first providing a substrate having a surface onto which a multifunctional organic layer is to be deposited. A single evaporation source is provided that includes a mixture of at least two organic compounds. The organic compounds can be matrix materials, and dopants if desired, that are used in making electronic and photonic devices. The single evaporation source is heated for a sufficient time and at a sufficient temperature to provide deposition of the organic compounds onto the surface of the substrate to form the multifunctional organic layer.

As a feature of the present invention, multifunctional organic layers can be formed where the organic compounds are substantially uniformly distributed throughout the layer. This is accomplished by selecting organic compounds that have thermal properties that are similar to each other. When the mixture is evaporated from a single evaporation source, the compounds evaporate at the same temperature to provide substantially uniform distribution of the compounds within the multifuctional organic layer.

As a second feature of the present invention, organic compounds having dissimilar thermal properties are selected for admixture to provide the single evaporation source. Upon heating, the compounds evaporate at different temperatures and are deposited on the substrate in different relative amounts as the temperature is increased to thereby provide a multifunctional layer having a graded junction interface.

As a third feature of the present invention, organic matrix materials and dopants that have different thermal properties are first fused together to form a fusion mixture. The fusion mixture can be evaporated as a single evaporation source to form the desired multifunctional layer. The fusion mixture can be evaporated alone or in combination with other matrix materials and/or fusion mixtures. The fusion of the dopant with the matrix material, prior to evaporation and deposit onto the substrate, provides for uniform distribution of the dopant within the matrix material in the final multifunctional layer.

The above discussed and many other features and attendant advantages of the present invention will become better understood by reference to the detailed description when taken in conjunction with the accompanying drawings.

### BRIEF DESCRIPTION OF THE DRAWINGS

FIG. 1 is a simplified schematic diagram of a basic OLED.

FIGS. 2 (a-c) are pictorial representations of three different types of known exemplary organic junctions. Figure symbols: HTLs are shown as solid circles; ETLs are shown as hollow circles; and dopants are shown shade circles. FIG. 2(a) depicts a hetero-junction structure. FIG. 2(b) depicts a graded mixed (or junction) structure. FIG. 2(c) depicts a uniformly mixed structure.

FIG. 3 is a schematic diagram of the pressurized chamber heating system that was used to thermally fuse organic compounds prior to evaporation and deposition.

FIG. 4 is graph showing the current-voltage and brightness-voltage characteristics of device A.

FIG. 5 is a graph showing the efficiency-current characteristics of device A.

FIG. 6 is a graph showing the EL spectrum of device A.

FIG. 7 is a graph showing the current-voltage and brightness-voltage characteristics of device B.

FIG. 8 is a graph showing the efficiency-current characteristics of device B.

FIG. 9 is a graph of the EL spectrum of device B.

FIG. 10 is a graph of the current-voltage and brightness-voltage characteristics of the device C.

FIG. 11 is a graph of the efficiency-current characteristics of the device C.

FIG. 12 is a graph the EL spectrum of the device C.

FIG. 13 is a graph of the current-voltage and brightness-voltage characteristics of the device D.

FIG. 14 is a graph of the efficiency-current characteristics of the device D.

FIG. 15 is a graph of the EL spectrum of the device D.

FIG. 16 is a graph of the current-voltage and brightness-voltage characteristics of the device E.

FIG. 17 is a graph of the efficiency-current characteristics of the device E.

FIG. 18 is a graph of the EL spectrum of the device E.

FIG. 19 is a graph of the current-voltage and brightness-voltage characteristics of the device F.

FIG. 20 is a graph of the efficiency-current characteristics of the device F.

FIG. 21 is a graph of the EL spectrum of the device F.

FIG. 22 is a graph of the current-voltage and brightness-voltage characteristics of the device G.

FIG. 23 is a graph of the efficiency-current characteristics of the device G.

FIG. 24 is a graph of the EL spectrum of the device G.

FIG. 25 is a graph of the current-voltage and brightness-voltage characteristics of the device H.

FIG. 26 is a graph of the efficiency-current characteristics of the device H.

FIG. 27 is a graph of the EL spectrum of the device H.

FIG. 28 is a graph of the current-voltage and brightness-voltage characteristics of the device I.

FIG. 29 is a graph of the efficiency-current characteristics of the device I.

FIG. 30 is a graph of the EL spectrum of the device I.

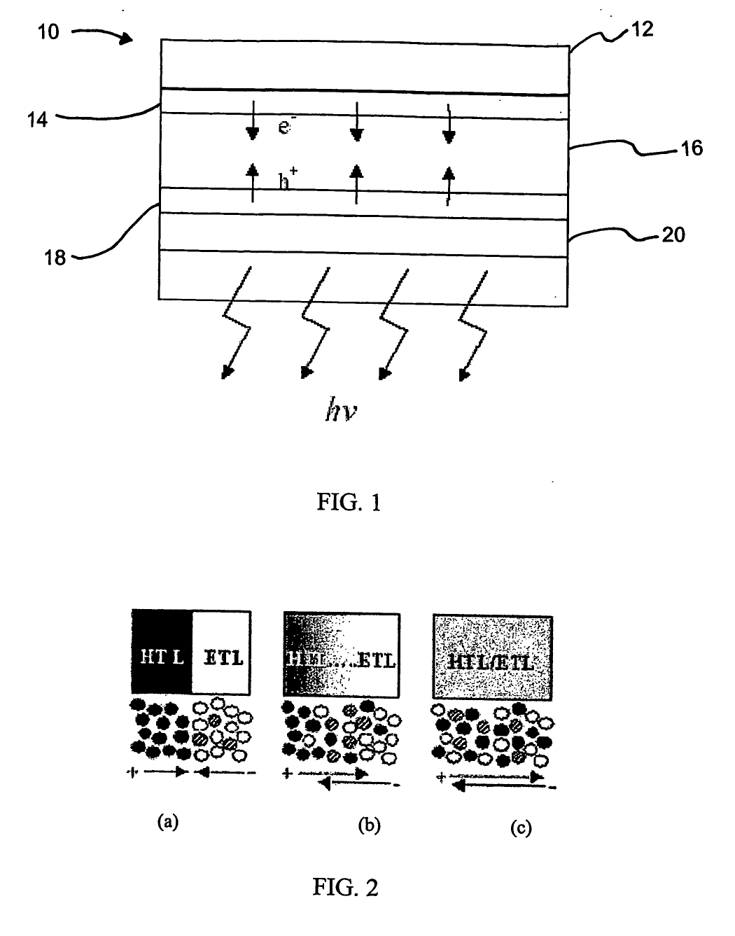

### DETAILED DESCRIPTION OF THE INVENTION

In accordance with the present invention, the multi-boat co-evaporation process is simplified by using one boat to form multifunctional organic layers that contain multiple (at least two) organic compounds. These compounds can be either pre-mixed or fused at precise ratios. This fusion process enables the organics to fuse into one component with high uniformity. The multifunctional organic layer can be the entire active medium for the organic device or it can be a particular layer of a multi-layer organic device.

An important aspect of the present invention is that only one heating source (boat) is required to prepare a layer of multi-functional organic thin film by the traditional thermal deposition process. This multifunctional organic thin film could be the entire organic device (for example an OLED), or it can be an important layer of a multiplayer organic device (for example, one active layer of an OLED). An important criterion for preparing this multifunctional organic layer is the selection of organic compounds, as well as the preparing (mixing or fusing) of these compounds. According to different characteristics of the organic compounds and the requirements for the thin films, the organic mixtures should be prepared in different ways.

The methods in accordance with the present invention can be used in making a wide variety of electronic and photonic devices that include at least one multifunctional organic layer. Exemplary devices include Organic Light Emitting Diodes (OLEDs), Organic Thin Film Transistors (OTFTs), Organic Solar Cells (OSCs), Organic Bistable Devices (OBDs), and Organic Diodes (ODs). The method basically involves first providing a substrate having a surface onto which a multifunctional organic layer is to be deposited as part of the fabrication process for one of the above described devices. The substrate can be any of the known materials that are used as substrates for electronic and photonic devices. For example, glass/indium tin oxide (ITO) substrates are commonly used in OLEDS.

A single evaporation source is provided that includes a mixture of at least two organic compounds. The organic compounds can be matrix materials, and dopants if desired, that are used in making the electronic or photonic device. The single evaporation source is heated for a sufficient time and at a sufficient temperature to provide deposition of the organic compounds onto the surface of the substrate to form the multifunctional organic layer. The temperatures, temperature gradients and time of heating will vary depending upon the particular matrix materials, dopants and fused mixtures of matrix material and dopants that are present in the single evaporation source. The specific temperatures and times that will be sufficient to evaporate the compounds and deposit the multifunctional organic layers can be determined by routine experimentation, if necessary, for each combination of organic compounds.

We describe several exemplary methods below that are based on using different organic matrix materials and dopants that have similar or dissimilar thermal properties. The thermal properties are melting point and/or glass transition temperature (T_{g}). “Similar” is used in its normal sense to mean thermal properties that are substantially the same, but not necessarily identical. For example, melting points and T_{g}'s that are within 10° C. of each other are considered to be “similar.” Of course, our invention is not limited to the following exemplary embodiments that are also referred to as “cases.”

Embodiment 1 (Case 1): Thin films having one or more host matrix materials with or without dopant. All materials have similar thermal property (melting point, glass transition point). In this case, uniform multifunctional films are formed.
(a) If the materials are all host matrix materials (at least two compounds, for example ETL and HTL) and the thermal properties of these compounds are similar to each other, they can be mixed directly and ground into fine powders. This mixture of compounds can be used as a sole source for the thermal evaporation and the resulted film will contain two (or more) functionalities. For example, one can prepare an organic thin film with both hole and electron transporting capability by mixing the ETL and HTL compounds. This is the easiest way to prepare the multi-functional film. The finished film will be uniformly containing two (or more) compounds, since the thermal properties of those compounds are similar. The term “uniformly containing” is intended to mean that the organic compounds that have been deposited onto the substrate are distributed substantially uniformly throughout said multifunctional layer. The term is to be interpreted in its normal sense to mean that there may be some minor areas of non-uniformity of distribution.
(b) The above embodiment can also be expanded to include dopant(s). If the added dopant has a similar thermal property, it can be mixed with host compounds and grinded into fine powder (only if needed). This mixture can then be used as the sole source to prepare the thin film though the evaporation process. Again, the dopant and the host materials will be uniformly distributed all over the thin film due to the similar thermal properties.

Embodiment 2 (Case 2): Thin films consist of two host matrix materials, with or without dopants. The organic materials have dissimilar thermal properties. In this case, organic thin films with graded junction interfaces are formed.
(a) If the selected materials are all host matrix materials (at least two compounds, for example ETL and HTL), but the thermal properties of these two or more compounds are not similar to each other, they can be mixed directly and ground into fine powders. This mixture of compounds can be used as a sole source for the thermal evaporation and the resulting film will contain two (or more) functionalities. This kind of mixture can be used to form organic layers using the thermal evaporation process and it is expected that the materials will be distributed in a gradient distribution with the low melting-point material deposited at a faster rate in the beginning. If necessary, the electrical current for evaporation can be slowly ramped up so the low melting point organic compound can be evaporated first. For example, one can prepare an organic thin film with both hole and electron transporting capability by mixing the ETL and HTL compounds. The concentration of the ETL and HTL is distributed as a gradient in an opposite way, if HTL has a lower melting point than the ETL. For example, the concentration of HTL decreases slowly, ideally from 100% down to 0%. In the meantime, the ETL increases from 0% to 100%. This positive and negative gradient of ETL and HTL overlaps within an OLED.
(b) Similar to what has been described above, one can add dopants into the mixture. There are many known dopants that may be added and they can be added in different ways. For example, the dopant(s) may be added to one or more host material(s) or we can introduce different dopants during different parts of the procedures. It should be noted that adding dopants in this situation is somewhat not so trivial, due to the requirement of dopant distribution. Details are described below.

Embodiment (Case 3): High temperature and high-pressure fusion of organic compounds for thin film preparation.

In the past, one of the major problems of using organic dopants is the non-uniformity and the aggregation of organic dopants. If the organic host matrix material(s) and the dopant(s) have different thermal properties, it is difficult to use the mixture directly as the evaporation source to prepare multifunctional thin films. This is because the dopant might evaporate much slower or faster than the host material. The result is a non-uniform distribution of dopant in the matrix, even when finely ground powder is used. In order to overcome this problem, a high temperature and high-pressure process designed to fuse the dopants and the host material together has been developed by us to resolve this problem. The fused compound, containing the host (matirx) materials and the dopants, is designed to achieve a highly uniform distribution of dopants. For example, if the host matrix materials and the dopant of the graded junction layer (case 2) have a very different thermal property, and one requires having the dopants to be with the ETL. The ETL can be fused with the dopant to ensure the uniform distribution of the dopant within the ETL layer.

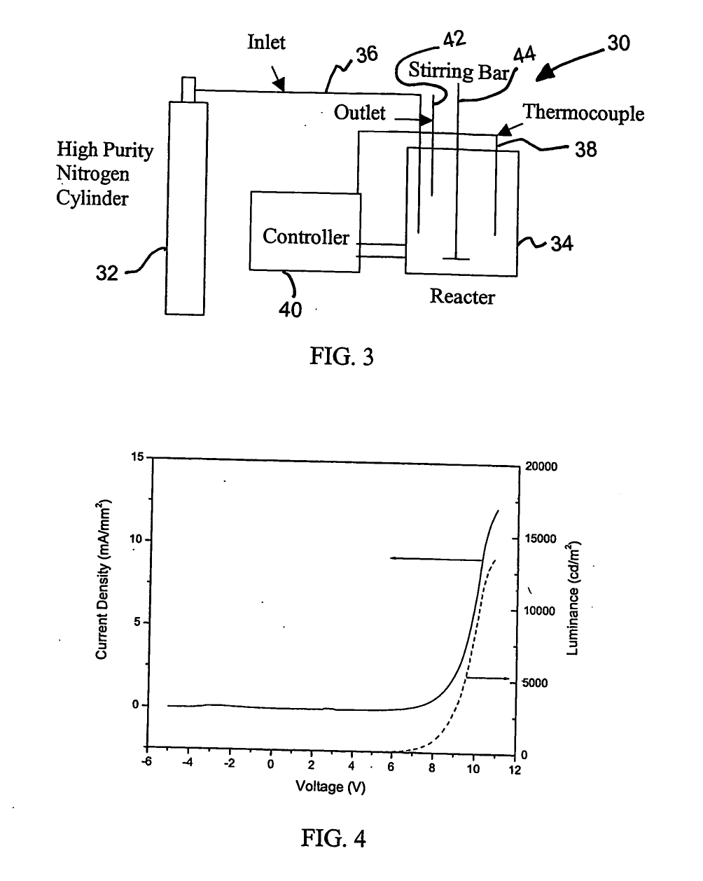

FIG. 3 shows an exemplary pressurized chamber system 30 with heating capability for the fusion of organic compounds. The system 30 includes a high purity nitrogen cylinder 32 that provides nitrogen to reactor 34 through inlet 36. A thermocouple 38 is provided that is controlled by controller 40. The system further includes at outlet 42 and stirring bar 44.

The idea of fusing two (or more) compounds together is rather simple. When the mixed organic compounds are heated up above the melting points of the compounds (sometimes only above one of the melting points is acceptable), all the compounds will be melted and form a very uniform mixture of liquid. If necessary, the stirring bar 44 can be used to ensure a uniform mixture. In reality, when heated up, the organic compound usually sublimates before it is melted, hence a high pressure is required to ensure the compounds will be melted, not sublimated.

The above-described three embodiments of the present invention can be used to conveniently control the ratio of the matrix materials and the concentration of the dyes (dopants). As a result, the thermal deposition processes become much easier The decision regarding which of the above three embodiments should be used, either alone or in combination, will depend upon the different properties of the materials used and the type of thin film needed.

Examples of practice are as follows:

For all the OLED devices described in the following examples, glass/ITO substrates are used as the substrate. The ITO substrates were prepared by the known UV ozone process after a careful cleaning process that involved sonication of the substrate in alcohol and acetone, respectively. Fabrication of the devices was carried out under approximately 3×10⁻⁶ torr vacuum. To improve the electron injection, a bilayer cathode composed of 5 Å LiF and 1000 Å of A1 was used. The vacuum chamber was equipped with six sources and a thickness monitor. The device I-V curves were measured using a Keithley 236 SMU operated by a PC. The brightness was determined using a PR 650 photometer.

### EXAMPLE 1

### Device A: Single Layer Organic Multifunctional Thin Film Containing Alq₃ and NPD for OLEDs (Example of Case 2)

We utilized Alq₃ as the electron transport and emitting material and NPD as the hole transport material. The glass transition temperature (Tg) of Alq₃ is about 175° C. [5] and the Tg of NPD is about 95° C. [6] A mixture of 12.1 mg Alq₃ and 13.8 mg NPD was ground into fine powder and put into a heating boat. This mixture of compounds was directly used to deposit a multifunctional organic thin film. NPD is the hole-transport material and Alq₃ has electron transport and light-emitting functions. The device structure of device A was:
ITO/NPD+Alq₃(490 Å)/LiF(5 Å)/A1(1000 Å).
   “+” is used to show that these two compounds are obtained by directly mixing and sole-source evaporation. For example, NPD+Alq₃ in this example means that NPD and Alq₃ are mixed together to form a single powder that is then evaporated as a sole-source. “A:B” is used below to represent that compound A and compound B are fused together prior to evaporation. “/” is used in its conventional sense to delineate separately deposited layers.

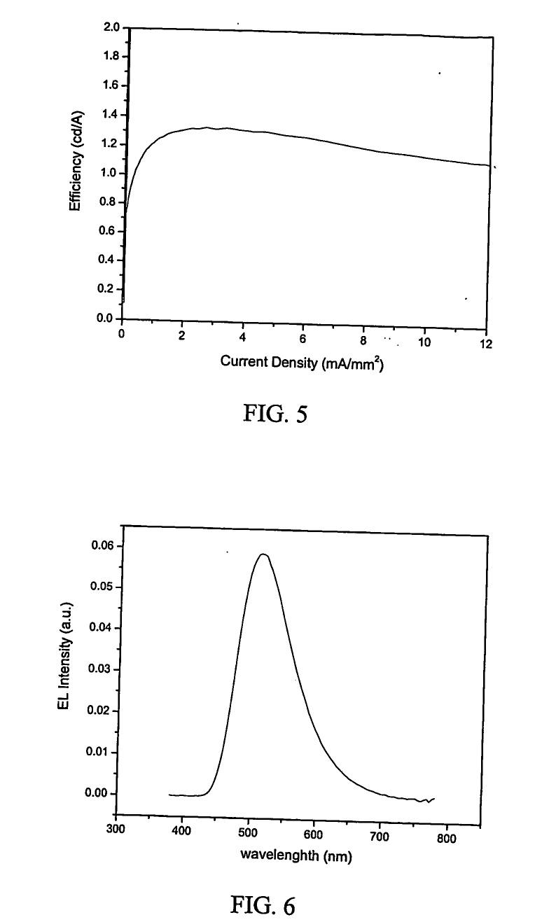

The OLED of this example is a simple structure and it is easy to fabricate since it only includes one single organic layer. The ratio of Alq₃ and NPD in this example is not necessarily optimized, and it could be a little different. The performance characteristics of this device are shown in FIGS. 4-6. This performance is comparable to the bilayer OLED composed of a NPD/Alq₃ bilayer structure. The structure may be optimized and the performance may be improved. In the same manner, we prepared the bilayer OLED with structure ITO/NPD(400 Å)/Alq₃(600 Å)/LiF(5 Å)/A1(1000 Å). The brightness of this OLED is almost same as ITO/NPD+Alq₃(490 Å)/LiF(5 Å)/A1(1000 Å), but with a higher maximum efficiency of about 4.9 cd/A.

### EXAMPLE 2

### Device B: Single Bipolar Transport Layer OLEDS Consisting of Alq₃ and NPD and Dopants (Example of Case 2 and Case 3)

In this example we used 10-(2-benzothiazolyl)-1,1,7,7-tetramethyl-2,3,6,7-tetrahydro-1H,5H,11H-[1]benzo-pyrano[6,7,8-ij]quinolizin-11-one (C545T) [2] as the green dopant dye. C545T has a melting point of 234.3° C. [7]. A fine powder of mixture of 96.5 mg NPD and 3.3 mg C545T was heated to 168° C. and kept at this temperature about 1 hour under 200 psi high purity nitrogen protection using the system shown in FIG. 3. This procedure can be modified a little by adopting different temperatures and pressures of nitrogen with or without stirring. At this step NPD and C545T are melted together, mixed uniformly and then cooled. Then 11.7 mg Alq₃ is added into 11.5 mg of the NPD and C545T mixture, which was prepared in the first step. The weight ratio of these three materials in this mixture is NPD(11.1 mg):C545T(0.38 mg)+Alq₃(11.7 mg). The mixture of Alq₃, NPD and C545T was ground into fine powder and put into a heating source. This kind of mixture can be utilized to directly deposit an organic film.

Traditional thermal deposition systems and techniques were used to fabricate devices in accordance with this example of the present invention. The ITO substrates were prepared by the known UV ozone process after careful cleaning. A thin layer of PEDOT was spin-coated onto clean ITO coated glass under 4 K/min within 1 minute. Under about 3×10⁻⁶ torr vacuum this mixture was deposited onto the substrate at a rate of about 2 to 3 Å/s. To improve the electron injection, a 5 Å LiF layer was deposited prior to deposition of a 1000 Å A1 cathode. The LiF layer was used as an electron-injection layer. The structure of device B was:
ITO/PEDOT/NPD:C545T+Alq₃(800 Å)/LiF(5 Å)/A1(1000 Å).

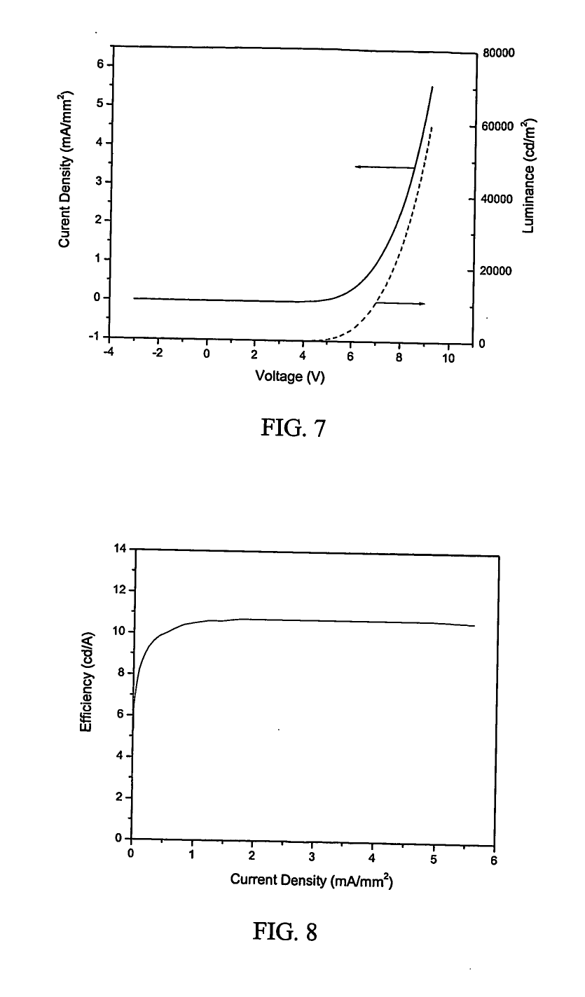

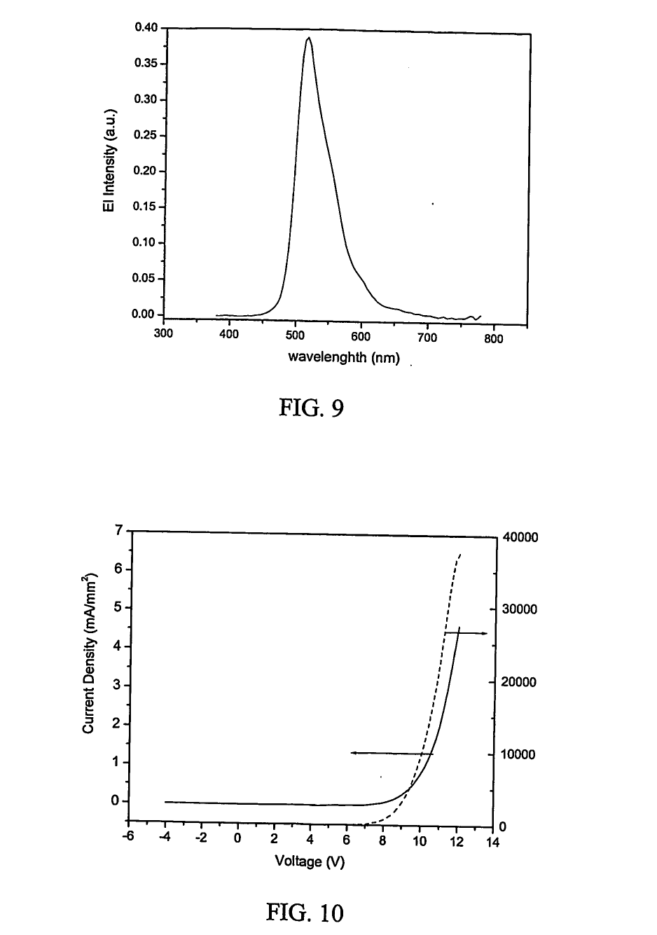

OLEDs of the type described in this example are also very easy to fabricate since it only includes one single organic layer deposition. And the weight ratio of these three materials can be controlled and changed easily. The performance characteristics of device B are set forth in FIGS. 7-9.

### EXAMPLE 3

### Device C: Mixed-Layer OLEDS with Three Function Layers and Green Dye (Example of Case 2 and Case 3)

A fine powder of mixture of 9.4 mg NPD and 0.91 mg C545T was heated to 210° C. and kept at this temperature about 1 hour under 300 psi high purity nitrogen protection. This procedure can be modified a little by adopting different temperature and pressure of nitrogen with or without stirring. At this step NPD and C545T are melted together, mixed uniformly and cooled. Then 14 mg Alq₃ is added into the NPD and C545T mixture, which was prepared from the first step. The weight ratio of these three materials in this mixture is NPD(9.4 mg):C545T(0.91 mg)+Alq₃(14 mg). The mixture of Alq₃, NPD and C545T is ground into fine powder and put into a heating source. This kind of mixture can be utilized to deposit organic film directly.

Traditional thermal deposition techniques were again used to fabricate the devices in this example. The ITO substrates were prepared by the UV ozone process after careful cleaning. A thin layer of PEDOT was spin-coated onto clean ITO coated glass under 4 K/min within 1 minute. Under about 3×10⁻⁶ torr vacuum a NPD hole transport layer, this mixture and an Alq₃ electron transport layer were deposited onto the substrate sequentially at a rate of about 2 to 3 Å/s. To improve the electron injection, 5 Å LiF deposited prior to 1000 Å A1 cathode was used as an electron-injection layer. The structure of device C was:
ITO/PEDOT/NPD(110 Å)/NPD:C545T+Alq₃(400 Å)/Alq₃(400 Å)/LiF(5 Å)/A1(1000 Å).

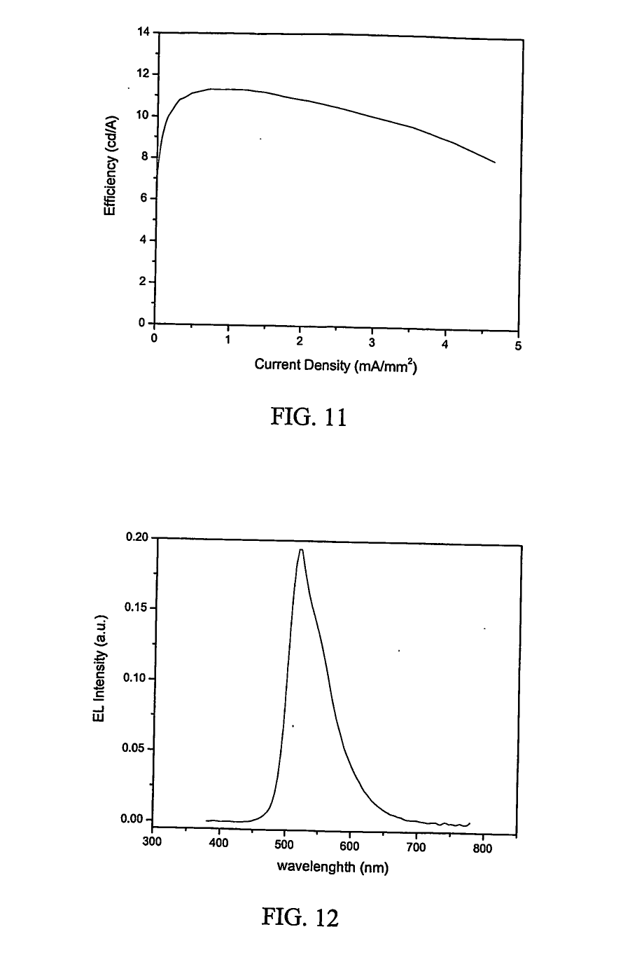

This kind of OLED should be easier to fabricate compared with the traditional dye doping devices. And the weight ratio of these three materials can be controlled and changed easily. The performance characteristics of device C are set forth in FIGS. 10-12.

### EXAMPLE 4

### Device D: Mixed-Layer OLEDs with Three Function Layers and Yellow Dye (Example of Case 2 and Case 3)

A fine powder of mixture of 11.94 mg NPD and 0.26 mg Rubrene is heated to 174° C. and kept at this temperature about 1 hour under 270 psi high purity nitrogen protection using the system shown in FIG. 3. This procedure can be modified a little by adopting different temperature and pressure of nitrogen with or without stirring. At this step NPD and Rubrene are melted together and mixed uniformly. Then 13.9 mg Alq₃ is added into NPD and Rubrene mixture, which is prepared from the first step. The weight ratio of these three materials in this mixture is NPD(11.94 mg):Rubrene(0.26 mg)+Alq₃(13.9 mg). The mixture of Alq₃, NPD and Rubrene is ground into fine powder and put into a heating source. This kind of mixture can be utilized to deposit organic film directly.

Traditional thermal deposition systems and techniques are used to fabricate the exemplary devices. The ITO substrates are prepared by UV ozone process after careful cleaning. Under about 3×10⁻⁶ torr vacuum a NPD hole transport layer, this mixture and an Alq₃ electron transport layer are deposited onto the substrate sequentially at a rate of about 2˜3 Å/s. To improve the electron injection, 5 Å LiF deposited prior to 1000 Å A1 cathode is used as electron-injection layer. The structure of device D was:
ITO/NPD(120 Å)/NPD:Rubrene+Alq₃(780 Å)/Alq₃(150 Å)/LiF(5 Å)/A1(1000 Å).

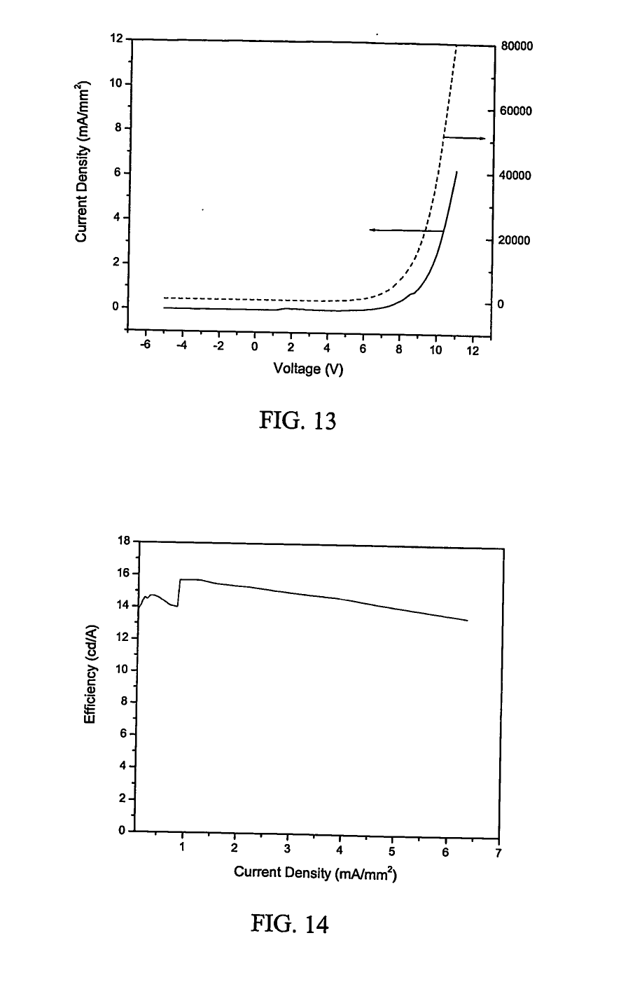

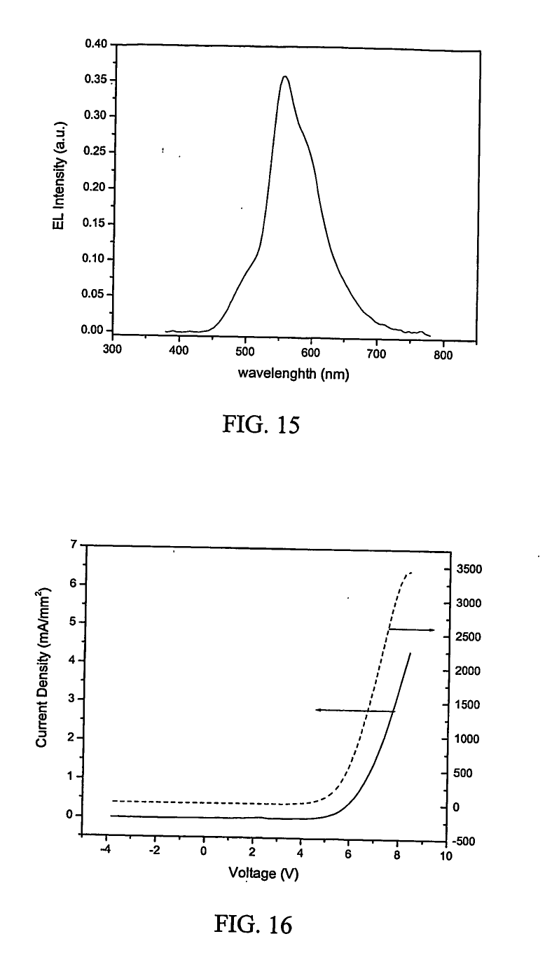

This kind of OLEDs should be easier to fabricate compared with the traditional dye doping devices. And the weight ratio of these three materials can be controlled and changed easily. The performance characteristics of device C is shown in FIGS. 13-15.

### EXAMPLE 5

### Device E: Blue OLEDs with Four Function Layers and Blue Dye (Example of Case 1 and Case 3)

A fine powder of mixture of 9.53 mg NPD and 0.98 mg DPVBi was heated to 218° C. and kept at this temperature about 1 hour under 200 psi high purity nitrogen protection using the system shown in FIG. 3. This procedure can be modified a little by adopting different temperature and pressure of nitrogen with or without stirring. At this step NPD and DPVBi were melted together, mixed uniformly and cooled. The weight ratio of the two materials in this mixture was NPD(9.53 mg):DPVBi(0.98 mg). The mixture was ground into fine powder and put into a heating source. This kind of mixture can be utilized to deposit organic film directly.

Traditional thermal deposition systems are used to fabricate the devices in accordance with this example. The ITO substrates were prepared by the known UV ozone process after careful cleaning. A thin layer of PEDOT was spin-coated onto clean ITO coated glass under 4 K/min within 1 minute. Under about 3×10⁻⁶ torr vacuum, a NPD hole transport layer, this mixture, a BCP hole block layer and an Alq₃ electron transport layer were deposited onto the substrate sequentially at a rate of about 2 to 3 Å/s. To improve the electron injection, 5 Å LiF deposited prior to 1000 Å A1 cathode was used as an electron-injection layer. The structure of device E was:
PEDOT/NPD(400 Å)/NPD:DPvBi(200 Å)/BCP(50 Å)/Alq₃(300 Å)/LiF(5 Å)/A1(1000 Å).

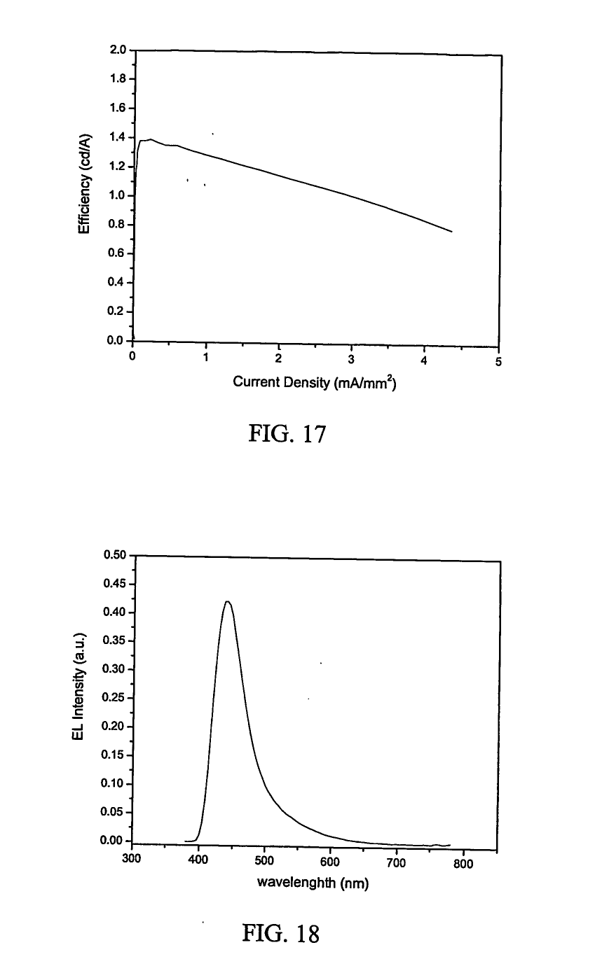

The kind of OLED in this example should be easier to fabricate compared with the traditional dye doping devices. And the weight ratio of these two materials can be controlled and changed easily. The performance characteristics of device B are shown in FIGS. 16-18.

### EXAMPLE 6

### Device F: White OLEDs with Four Function Layers and Two Dyes (Example of Case 1 and Case 3)

The white OLEDs are more complicated than single color devices since traditional white OLEDs always include more organic layers. The white OLEDs structures and the fabrication procedures are greatly simplified when methods in accordance with the present invention are utilized to fabricate these devices. In this example, a fine powder of mixture of 15.8 mg NPD, 0.14 mg Rubrene and 0.95 mg DPVBi was heated to 218° C. and kept at this temperature about 1 hour under 200 psi high purity nitrogen protection using the system shown in FIG. 3. This procedure can be modified a little by adopting different temperatures and pressures of nitrogen with or without stirring. At this step NPD, Rubrene and DPVBi are melted together, mixed uniformly and cooled. The weight ratio of the three materials in this mixture is NPD(15.8 mg):Rubrene(0.1415 mg):DPVBi(0.95 mg). The mixture is ground into fine powder and put into a heating source. This kind of mixture can be utilized to deposit organic film directly.

Traditional thermal deposition systems are used to fabricate the devices in accordance with this example. The ITO substrates were prepared by the known UV ozone process after careful cleaning. A thin layer of PEDOT was spin-coated onto clean ITO coated glass under 4 K/min within 1 minute. Under about 3×10⁻⁶ torr vacuum, a NPD hole transport layer, this mixture, a BCP hole block layer and an Alq₃ electron transport layer were deposited onto the substrate sequentially at a rate of about 2 to 3 Å/s. To improve the electron injection, sA LiF deposited prior to the 1000 Å A1 cathode was used as electron-injection layer. The structure of device F was:
PEDOT/NPD(400 Å)/NPD:DPVBi:Rubrene(200 Å)/BCP(260 Å)/Alq₃(300 Å)/LiF(5 Å)/A1(1000 Å)

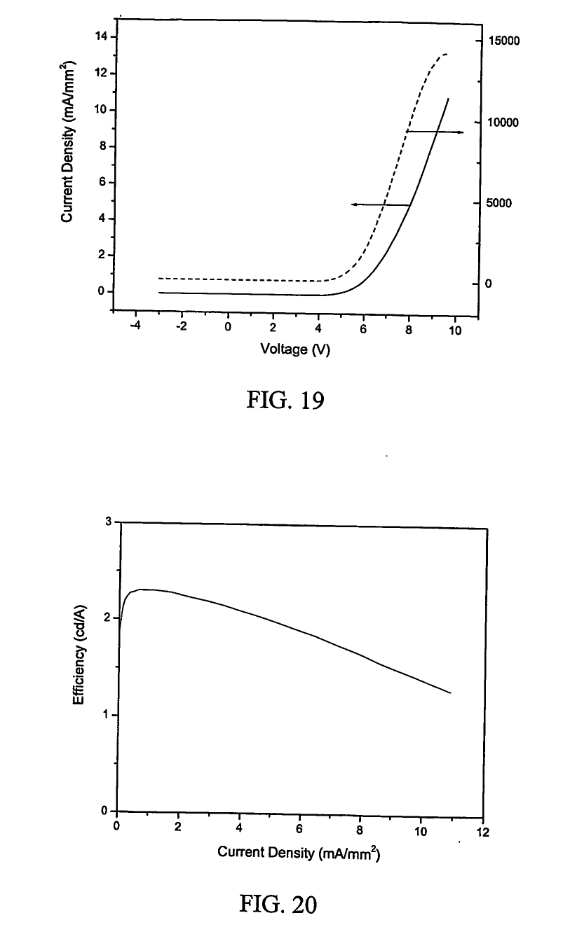

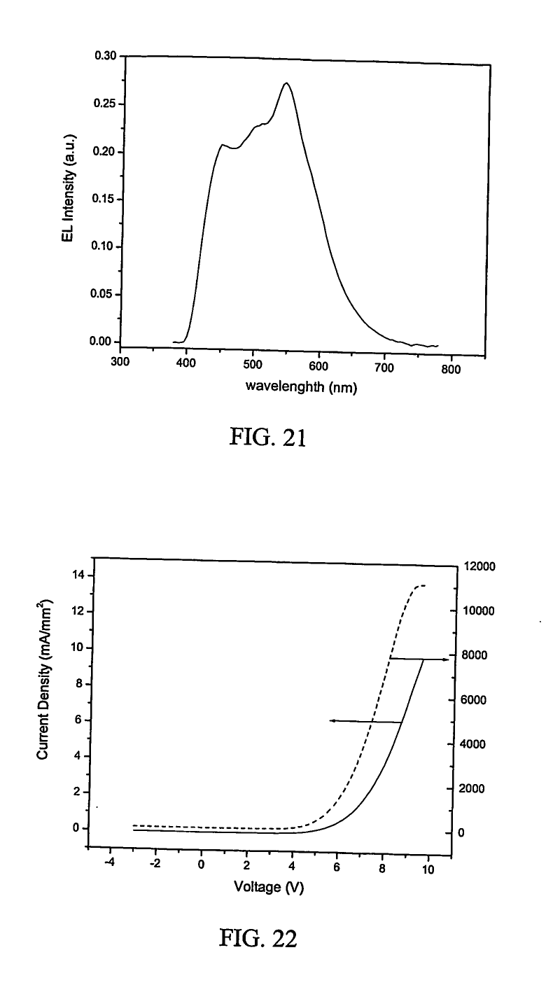

The kind of OLEDs made in accordance with this example should be much easier to fabricate compared with the traditional dye doping devices. And the weight ratio of these two materials can be controlled and changed easily. Accordingly, the better ratios for white light may be chosen. The performance characteristics of this device F are shown in FIGS. 19-21.

### EXAMPLE 7

### Device G: White OLEDs with Four Function Layers and Three Dyes (Example of Case 1 and Case 3)

A fine powder of mixture of 13.3 mg NPD, 0.07 mg Rubrene, 0.12 mg C545T and 0.68 mg DPVBi was heated to 218° C. and kept at this temperature about 1 hour under 200 psi high purity nitrogen protection using the system shown in FIG. 3. This procedure can be modified a little by adopting different temperatures and pressures of nitrogen with or without stirring. At this step NPD, Rubrene, C545T and DPVBi were melted together, mixed uniformly and cooled. The weight ratio of the four materials in this mixture was NPD(13.3 mg):Rubrene(0.07 mg):C545T(0.12 mg):DPVBi(0.68 mg). The mixture is ground into fine powder and put into a heating source. This kind of mixture can be utilized to deposit organic film directly.

Traditional thermal deposition systems are used to fabricate the devices in accordance with this example. The ITO substrates were prepared by the known UV ozone process after careful cleaning. A thin layer of PEDOT was spin-coated onto clean ITO coated glass under 4 K/min within 1 minute. Under about 3×10⁻⁶ torr vacuum, a NPD hole transport layer, this mixture, a BCP hole block layer and an Alq₃ electron transport layer were deposited onto the substrate sequentially at a rate of about 2 to 3 Å/s. To improve the electron injection, 5 Å LiF was deposited prior to the 1000 Å A1 cathode as an electron-injection layer. The structure of device F was:
PEDOT/NPD(400 Å)/NPD:C545T:DPVBi:Rubrene(200 Å)/BCP(300 Å)/Alq₃(300 Å)A1(5 Å))/A1(1000 Å).

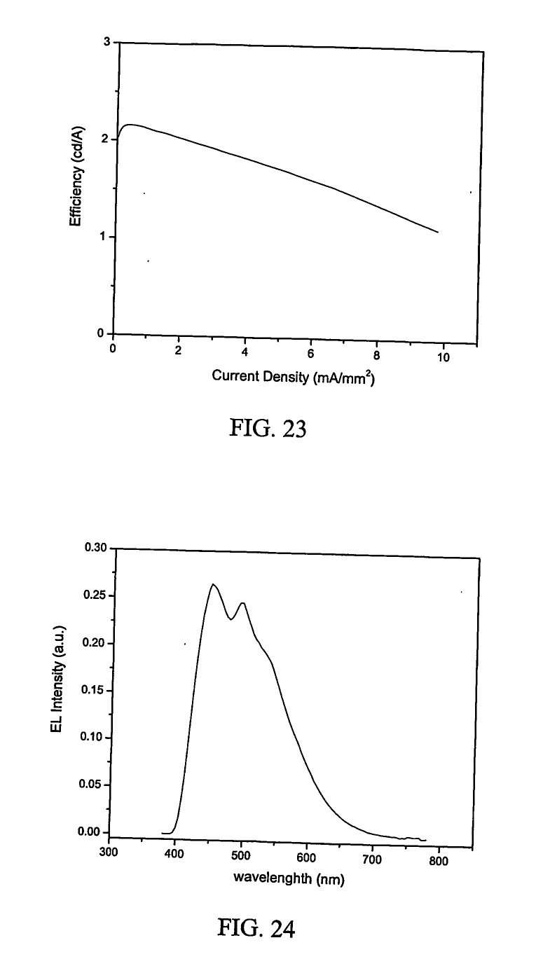

The kind of OLEDs made in accordance with this example should be much easier to fabricate compared with the traditional dye doping devices. And the weight ratio of these two materials can be controlled and changed easily. Accordingly, one of ordinary skill can more easily optimize the mixture ratios for white light. The performance characteristics of device G are shown in FIGS. 22-24.

### COMPARISON EXAMPLE 1

### Device H: Single Bipolar Transport Layer OLEDs Consisting of Alq₃ and NPD and Dopants (Example for Comparison with Device B)

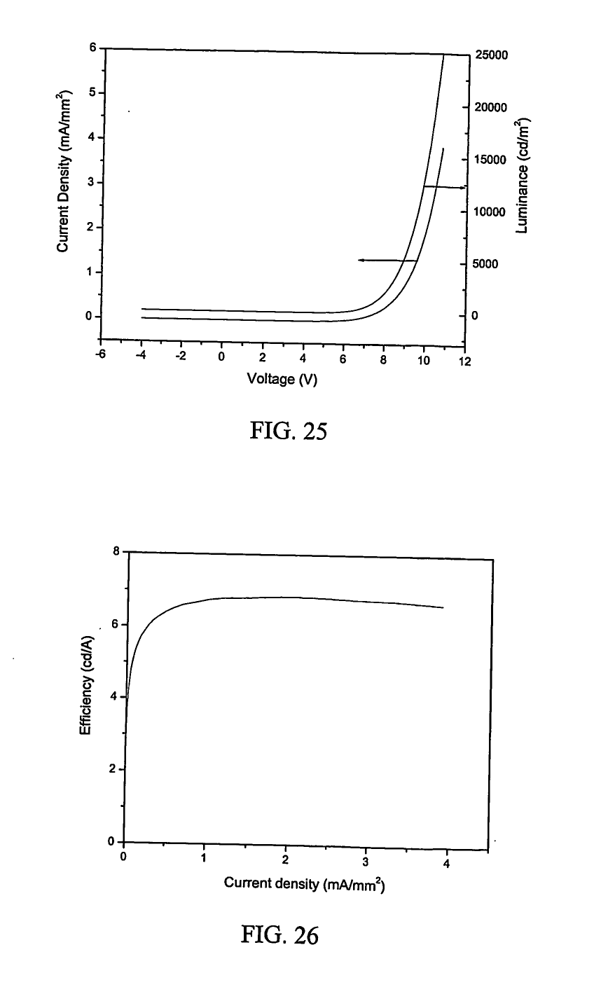

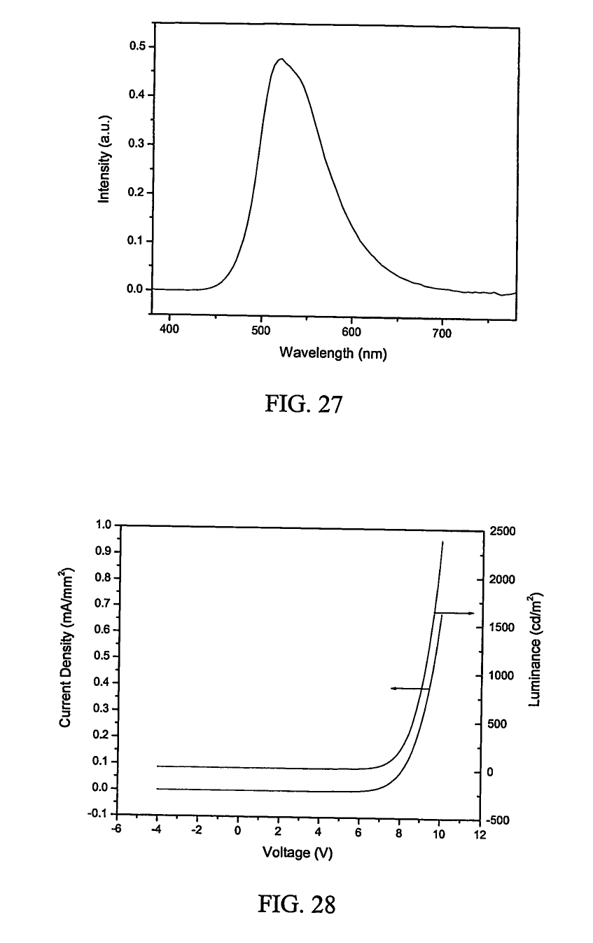

We prepared an OLED (device H) with the same ratio of all the materials as device B, but without using the fusing process as set forth in Example 2. The performance of device H was found to be a little worse compared with device B. The performance characteristics of device H are shown in FIGS. 25-27.

### COMPARISON EXAMPLE 2

### Device I: Single Bipolar Transport Layer OLEDS Consisting of Alq₃ and NPD and Dopants (Example for Comparison with Device D)

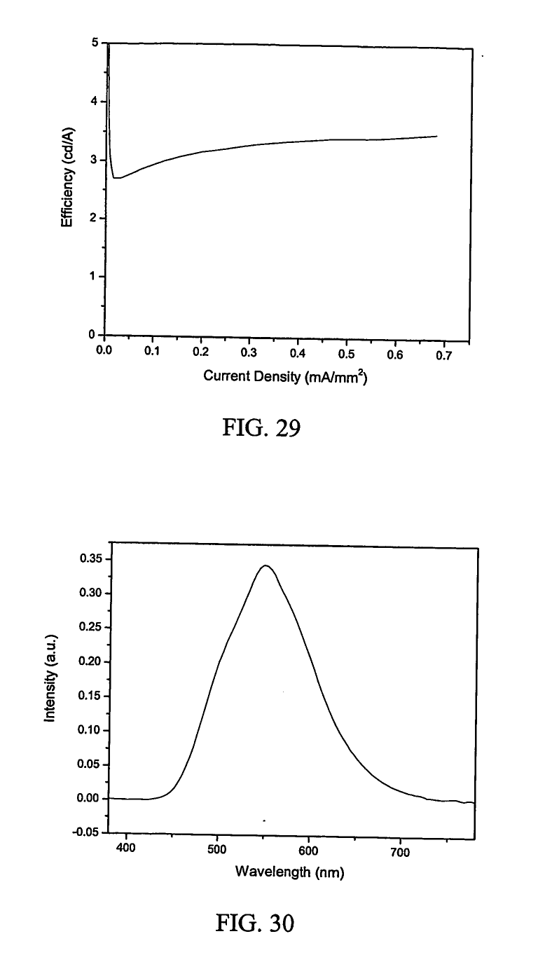

We prepared an OLED with the same ratio of all the materials as device D, but without using the fusing process as set forth in Example 4. The performance of device I was found to be much worse compared with device D. The performance characteristics of device I are shown in FIGS. 28-30.

As can be seen from the above examples, the present invention provides a new single-source evaporation technology for preparing complex organic thin films. The advantages of the single-source evaporation methods of the present invention include easy and simple device fabrication, even for very complicate devices. The present invention has been demonstrated with seven examples of OLED fabrication, especially in mixed-layers and doping layers. It will be apparent to those of ordinary skill in the art that the invention is not limited to OLEDs, but may be used in the fabrication of a wide variety of electronic and photonic devices.

Having thus described exemplary embodiments of the present invention, it should be noted by those skilled in the art that the within disclosures are exemplary only and that various other alternatives, adaptations and modifications may be made within the scope of the present invention. Accordingly, the present invention is not limited to the above preferred embodiments and examples, but is only limited by the following claims.

### BIBLIOGRAPHY

[1] C. W. Tang and S. A. Vanslyke, Appl Phys. Lett. 5, 913 (1987).
[2] J. L. Fox, C. H. Chen, U.S. Pat. No. 4,736,032 (1988).
[3] Anna B. Chwang, Raymond C. Kwong, and Julie J. Brown, Appl. Phys. Lett. 80, 725 (2002).
[4] Dongge Ma, C. S. Lee, S. T. Lee, and L. S. Hung, Appl. Phys. Lett. 80, 3641 (2002).
[5] Naito K, Miura A, J. Phys. Chem., 97, 6240 (1993).
[6] Hisayoshi Fujikawa, Masahiko Ishii, Shizuo Tokito, and Yasunori Taga, Mat. Res. Soc. Symp. Proc., 621, Q3.4.1 (2000).
[7] H. W. Sands Corp. website, http://www.hwsands.com/productlists/oled/other/opaS545.htm

What is claimed is:

1. A method for use in making electronic and photonic devices wherein said devices include at least one multifunctional organic layer, said method comprising the steps of:
providing a substrate having a surface onto which a multifunctional organic layer is to be deposited;
providing a single evaporation source that comprises a mixture of at least two organic compounds; and
heating said single evaporation source for a sufficient time and at a sufficient temperature to provide deposition of said organic compounds onto the surface of said substrate to form said multifunctional organic layer.

2. A method for use in making electronic and photonic devices according to claim 1 wherein said single evaporation source comprises organic compounds selected from the group consisting of matrix materials and dopants.

3. A method for use in making electronic and photonic device according to claim 2 wherein said single evaporation source includes at least one dopant.

4. A method for use in malting electronic and photonic device according to claim 2 wherein said matrix material is selected from the group consisting of electron transport materials and hole transport materials.

5. A method for use in making electronic and photonic device according to claim 3 wherein said single evaporation source comprises a fusion mixture comprising at least one of said matrix materials that has been fused with at least one of said dopants.

6. A method for use in making electronic and photonic device according to claim 1 wherein said organic compounds have similar thermal properties.

7. A method for use in making electronic and photonic device according to claim 6 wherein said single evaporation source is heated for a sufficient time and at a sufficient temperature to form a multifunctional layer having said organic compounds distributed substantially uniformly throughout said multifunctional layer.

8. A method for use in making electronic and photonic devices according to claim 1 wherein said organic compounds have dissimilar thermal properties.

9. A method for use in making electronic and photonic device according to claim 8 wherein said single evaporation source is heated for a sufficient time and at a sufficient temperature to form a multifunctional layer having a graded junction interface.

10. A method for use in making electronic and photonic devices according to claim 1 wherein said devices are selected from the group consisting of organic light emitting diodes, organic thin film transistors, organic solar cells, organic bistable devices, and organic diodes.

11. A method for use in making an organic light emitting diode wherein said organic light emitting diode includes at least one multifunctional organic layer, said method comprising the steps of:
providing a substrate having a surface onto which a multifunctional organic layer is to be deposited;
providing a single evaporation source that comprises a mixture of at least two organic compounds; and
heating said single evaporation source for a sufficient time and at a sufficient temperature to provide deposition of said organic compounds onto the surface of said substrate to form said multifunctional organic layer.

12. A method for use in making an organic light emitting diode according to claim 11 wherein said single evaporation source comprises organic compounds selected from the group consisting of matrix materials and dopants.

13. A method for use in making an organic light emitting diode according to claim 12 wherein said single evaporation source includes at least one dopant.

14. A method for use in making an organic light emitting diode according to claim 12 wherein said matrix material is selected from the group consisting of electron transport materials and hole transport materials.

15. A method for use in making an organic light emitting diode according to claim 16 wherein said single evaporation source comprises a fusion mixture comprising at least one of said matrix materials that has been fused with at least one of said dopants.

17. A method for use in making an organic light emitting diode according to claim 11 wherein said organic compounds have similar thermal properties.

18. A method for use in making an organic light emitting diode according to claim 17 wherein said single evaporation source is heated for a sufficient time and at a sufficient temperature to form a multifunctional layer having said organic compounds distributed substantially uniformly throughout said multifunctional layer.

19. A method for use in making an organic light emitting diode according to claim 11 wherein said organic compounds have dissimilar thermal properties.

20. A method for use in making an organic light emitting diode according to claim 19 wherein said single evaporation source is heated for a sufficient time and at a sufficient temperature to form a multifunctional layer having a graded junction interface.
